(19) United States
(12) Patent Application Publication
(10) Pub. No.: US 2008/0303050 A1
(43) Pub. Date: Dec. 11, 2008

(54) LIGHT EMITTING MODULE

(75) Inventor: Chia-Te Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AMA PRECISION INC., Taipei (TW)

(21) Appl. No.: 12/131,931

(22) Filed: Jun. 3, 2008

(30) Foreign Application Priority Data
Jun. 6, 2007 (TW) 96120322

(51) Int. Cl. H01L 33/00

(52) U.S. Cl. 257/99; 257/E33.058

(57) ABSTRACT

A light emitting module includes a heat dissipation base, a circuit board and a light emitting diode (LED) package. The supporting surface of the heat dissipation base has a positioning structure. The circuit board is disposed on the supporting surface of the heat dissipation base, and it has an opening for exposing the positioning structure. The LED package is positioned at the positioning structure through the opening and is electrically connected to the circuit board.

### CROSS-REFERENCE TO RELATED APPLICATION

This application claims the priority benefit of Taiwan application serial no. 96120322, filed on Jun. 6, 2007. The entirety of the above-mentioned patent application is hereby incorporated by reference herein and made a part of this specification.

### BACKGROUND OF THE INVENTION

1. Field of the Invention

The invention relates to a light emitting module and, more particularly, to a light emitting module having a heat dissipation base.

2. Description of the Related Art

Since the luminous efficiency of a light emitting diode (LED) increases, the LED gradually replaces a fluorescent light and an incandescent bulb in many fields such as the light source of a scanner with a fast response speed, the backlight or front-light of a liquid crystal display device, lighting for the instrument panel of a vehicle, traffic lights and common lighting devices. Compared with the conventional bulbs, the LED has absolute vantage. The LED has a small volume, a long lifespan, a low driving voltage or current. However, along with the increase of the luminous power of the LED, the heat dissipation efficiency is an important factor affecting the reliability of the LED.

FIG. 1 is a sectional view showing a conventional LED module. As shown in FIG. 1, in a conventional LED module 100, pins 112 of a LED package 110 are soldered on a printed circuit board 120 first to allow an operation voltage to be transmitted to the LED package 110 via the printed circuit board 120. However, along with the increase of the luminous power of the LED package 110, the quantity of heat generated during the luminous process also rapidly increases. To prevent the LED package 110 from being overheated and damaged, the printed circuit board 120 is disposed on a heat dissipation base 130 to dissipate the heat via the heat dissipation base 130 and to increase the heat dissipation efficiency. However, the heat generated by the LED package 110 is conducted to the heat dissipation base 130 via the printed circuit board 120. Then the printed circuit board 120 resists dissipating heat and causes the bad heat dissipation efficiency of the LED module. In addition, the printed circuit board 120 should be fixed on a correct location on the heat dissipation base 130 to allow the LED package 110 to be located at the best location for increasing the luminous efficiency, which causes assembly working-hour and cost to increase.

### BRIEF SUMMARY OF THE INVENTION

The invention provides a light emitting module for solving problems that heat dissipation efficiency is bad, assembly working-hour is too long, and assembly cost is high in the conventional technology.

The light emitting module of the invention includes a heat dissipation base, a circuit board and a light emitting diode (LED) package. The supporting surface of the heat dissipation base has a positioning structure. The circuit board is disposed on the supporting surface of the heat dissipation base, and it has a first opening for exposing the positioning structure. The LED package is positioned at the positioning structure through the first opening and is electrically connected to the circuit board.

In one embodiment of the light emitting module, the LED package includes a LED chip, a plurality of pins and a encapsulated package. The pins are electrically connected to the LED chip, and the encapsulated package encapsulates the LED chip and part of each of the pins. The light emitting module may further include a fixing member for fixing the circuit board and the LED package to the heat dissipation base, and the fixing member has a second opening for exposing part of the encapsulated package. The light emitting module may further include a plurality of screws, and the fixing member is screwed to the heat dissipation base via the screws. The fixing member may keep a distance from lateral surfaces of the encapsulated package.

In one embodiment of the light emitting module, the light emitting module may further include a fixing member for fixing the circuit board and the LED package to the heat dissipation base, and the fixing member has a second opening for exposing the luminous surface of the LED package. The light emitting module may further include a plurality of screws, and the fixing member is screwed to the heat dissipation base via the screws.

In one embodiment of the light emitting module, the positioning structure is a recess.

In one embodiment of the light emitting module, the material of the heat dissipation base is metal.

In one embodiment of the light emitting module, the circuit board is a printed circuit board, a metal core printed circuit board or a flexible printed circuit board.

In one embodiment of the light emitting module, the light emitting module further includes a flexible thermal conductive material which is disposed between the supporting surface of the heat dissipation base and the LED package and is located at the positioning structure.

To sum up, in the light emitting module of the invention, since the LED package directly contacts the heat dissipation base, heat dissipation efficiency increases. The LED package can be precisely positioned via the positioning structure to save assembly working-hour and cost and increase luminous efficiency.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is a sectional view showing a conventional light emitting diode (LED) module.

FIG. 2 is a top view showing a light emitting module of one embodiment of the invention.

FIG. 3 is a sectional view showing the LED package in FIG. 2.

FIG. 4 is a top view showing a light emitting module of another embodiment of the invention.

FIG. 5 is a sectional view showing the light emitting module in FIG. 4 along an I-I line.

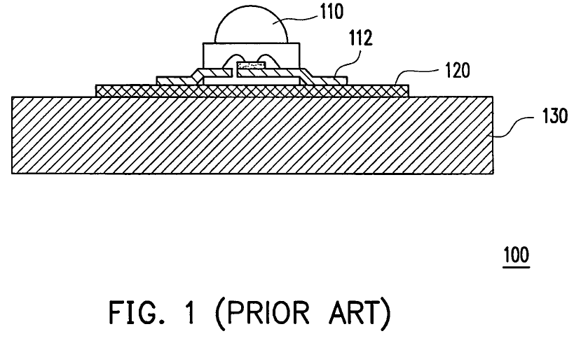

### DETAILED DESCRIPTION OF THE EMBODIMENTS

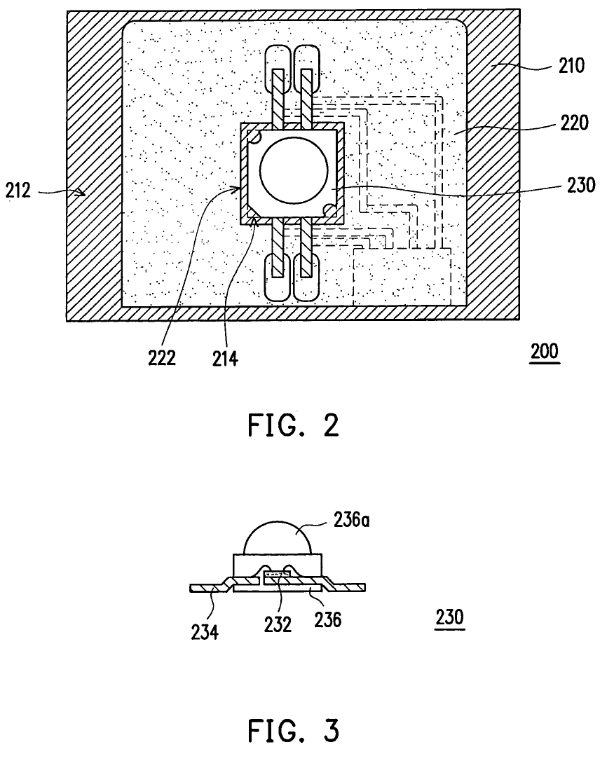

FIG. 2 is a top view showing a light emitting module of one embodiment of the invention, and FIG. 3 is a sectional view showing a LED package in FIG. 2. As shown in FIG. 2, a light emitting module 200 of the embodiment includes a heat dissipation base 210, a circuit board 220 and a light emitting diode (LED) package 230. The supporting surface 212 of the heat dissipation base 210 has a positioning structure 214. That is, the positioning structure 214 is disposed at one surface of the heat dissipation base 210, and the surface of the heat dissipation base 210 faces the LED package 230. The circuit board 220 is disposed on the supporting surface 212 of the heat dissipation base 210, and it has an opening 222 for exposing the positioning structure 214. The size of the opening 222 is slightly greater than the size of the LED package 230 to allow the LED package 230 to be positioned at the positioning structure 214 through the opening 222. Therefore, assembly difficulty caused by tolerance during assembly is avoided. Afterwards, the LED package 230 is electrically connected to the circuit board 220.

Since the LED package 230 and the heat dissipation base 210 are not separated by the circuit board 220, the heat of the LED package 230 is directly conducted to the heat dissipation base 210 and is dissipated to the environment via the heat dissipation base 210. Therefore, the light emitting module 200 of the embodiment has a good heat dissipation effect, and the LED package 230 is prevented from being overheated and damaged, which enhances the reliability of the light emitting module 200. Since the heat dissipation base 210 has the positioning structure 214, the LED package 230 can be easily positioned at the best location. In this way, when the light emitting module 200 is applied to various devices, the LED package 230 can have good light utilization efficiency. At the same working-hour, the assembly working-hour of the light emitting module 200 is shortened, and the assembly cost of the light emitting module 200 decreases.

The positioning structure 214 is a recess in the embodiment. The positioning structure 214 may also utilize other appropriate design to conveniently position the LED package 230. The material of the heat dissipation base 210 is metal or other material with a high heat conducting speed. The circuit board 220 of the embodiment may be a printed circuit board, a metal core printed circuit board, a flexible printed circuit board or other appropriate circuit board.

As shown in FIG. 2 and FIG. 3, the LED package 230 of the embodiment includes, for example, a LED chip 232, a plurality of pins 234 and a encapsulated package 236. The number of the LED chip 232 may be added to meet with an actual requirement. The pins 234 are electrically connected to the LED chip 232 via the components such as gold wires, bumps or other appropriate components. The pins 234 are also electrically connected to the circuit board 220 in a soldering mode, a flip chip mode or other appropriate mode. The encapsulated package 236 encapsulates the LED chip 232 and part of each of the pins 234 to protect the LED chip 232 and the electrical connection between the LED chip 232 and the pins 234. The encapsulated package 236 may also have a lens portion 236a to enhance the utilization efficiency of the light emitted by the LED chip 232. In detail, the positioning structure 214 of the embodiment is used to position the encapsulated package 236 of the LED package 230, and therefore, the design of the positioning structure 214 can be changed to cooperate with the change of the shape of the encapsulated package 236.

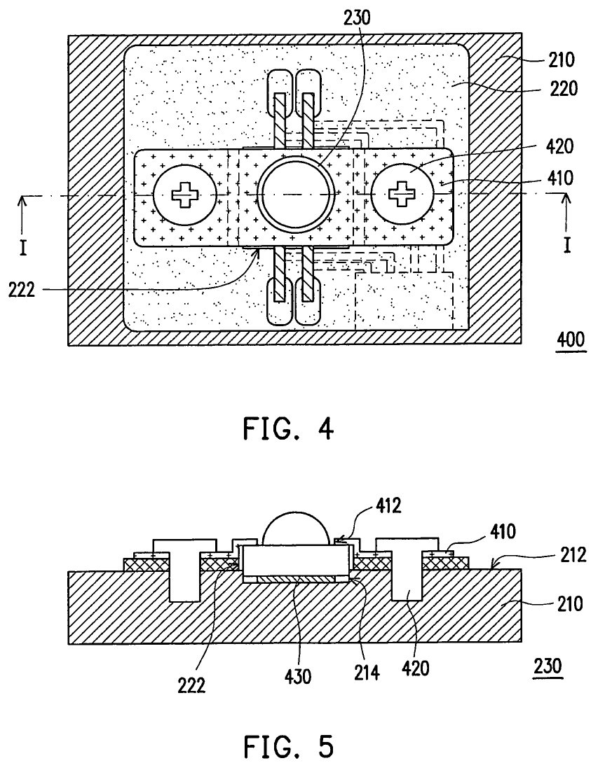

FIG. 4 is a top view showing a light emitting module of another embodiment of the invention, and FIG. 5 is a sectional view showing the light emitting module in FIG. 4 along an I-I line. As shown in FIG. 4 and FIG. 5, a light emitting module 400 of the embodiment is similar to the light emitting module 200 in FIG. 2, the same components are denoted with the same reference number, and the same components are not described for concise purpose. The light emitting module 400 of the embodiment further includes a fixing member 410 for fixing the circuit board 220 and the LED package 230 to the heat dissipation base 210, and the fixing member 410 has an opening 412 for exposing the luminous surface of the LED package 230. In detail, part of the encapsulated package 236 in FIG. 3 is exposed through the opening 412. For example, the lens portion 236a is exposed. The light emitting module 400 of the embodiment further includes a plurality of screws 420, and the fixing member 410 is screwed to the heat dissipation base 210 via the screws 420. The fixing member 410 may be fixed to heat dissipation base 210 via a tenon, a push pin or other appropriate components. The fixing member 410 keeps a distance from lateral surfaces of the encapsulated package 236 in FIG. 3 to avoid the displacement of the LED package 230 when the fixing member 410 is assembled.

The light emitting module 400 of the embodiment further includes a flexible thermal conductive material 430, and the flexible thermal conductive material 430 is disposed between the supporting surface 212 of the heat dissipation base 210 and the LED package 230 and is located at the positioning structure 214. In detail, the flexible thermal conductive material 430 is located between the encapsulated package 236 in FIG. 3 and the supporting surface 212 of the heat dissipation base 210. The flexible thermal conductive material 430 may be heat conducting glue, heat conducting grease or other appropriate flexible thermal conductive material for decreasing the heat resistance between heat dissipation base 210 and LED package 230.

To sum up, in the light emitting module of the invention, the LED package directly contacts the heat dissipation base, and the heat dissipation base has the positioning structure to precisely position the LED package. Therefore, the light emitting module of the invention has high heat dissipation efficiency, the short assembly working-hour, the low assembly cost, and the good luminous efficiency.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A light emitting module comprising:
a heat dissipation base whose supporting surface has a positioning structure;
a circuit board disposed on the supporting surface of the heat dissipation base and having a first opening for exposing the positioning structure; and
a light emitting diode (LED) package positioned at the positioning structure through the first opening and electrically connected to the circuit board.

2. The light emitting module according to claim 1, wherein the LED package comprises:
a LED chip;
a plurality of pins electrically connected to the LED chip; and
a encapsulated package encapsulating the LED chip and part of each of the pins.

3. The light emitting module according to claim 2 further comprising a fixing member for fixing the circuit board and the LED package to the heat dissipation base, wherein the fixing member has a second opening for exposing part of the encapsulated package.

4. The light emitting module according to claim 3 further comprising a plurality of screws, wherein the fixing member is screwed to the heat dissipation base via the screws.

5. The light emitting module according to claim 3, wherein the fixing member keeps a distance from lateral surfaces of the encapsulated package.

6. The light emitting module according to claim 1 further comprising a fixing member for fixing the circuit board and the LED package to the heat dissipation base, wherein the fixing member has a second opening for exposing an luminous surface of the LED package.

7. The light emitting module according to claim 6 further comprising a plurality of screws, wherein the fixing member is screwed to the heat dissipation base via the screws.

8. The light emitting module according to claim 1, wherein the positioning structure is a recess.

9. The light emitting module according to claim 1, wherein the material of the heat dissipation base is metal.

10. The light emitting module according to claim 1, wherein the circuit board is a printed circuit board, a metal core printed circuit board or a flexible printed circuit board.

11. The light emitting module according to claim 1 further comprising a flexible thermal conductive material which is disposed between the supporting surface of the heat dissipation base and the LED package and is located at the positioning structure.
